(19) United States
(12) Patent Application Publication
(10) Pub. No.: US 2009/0230473 A1
(43) Pub. Date: Sep. 17, 2009

(54) SEMICONUCTOR DEVICE AND METHOD FOR MANUFACTURING THE SAME

(75) Inventor: Yoji KITANO, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/391,561

(22) Filed: Feb. 24, 2009

(30) Foreign Application Priority Data
Mar. 11, 2008 (JP) 2008-061161

(51) Int. Cl. H01L 27/12; H01L 21/336

(52) U.S. Cl. 257/347; 438/151; 257/E27.112; 257/E21.415

(57) ABSTRACT

A semiconductor device includes a semiconductor layer formed on a substrate with an insulating film interposed therebetween, a gate insulating film formed on the semiconductor layer, a gate electrode which is formed on the gate insulating film, and includes a first region having a circular pattern in a plan view, a source and a drain which are respectively formed in the semiconductor layer inside and outside the first region in the plan view, and a wiring line which couples one of the source and the drain with the gate electrode.

### CROSS-REFERENCE TO RELATED APPLICATION

This application is based on and claims priority from Japanese Patent Application No. 2008-061161, filed on Mar. 11, 2008, the contents of which are incorporated herein by reference.

### BACKGROUND

1. Technical Field

The present invention relates to a semiconductor device and a method for manufacturing the semiconductor device. More particularly, the invention relates to the semiconductor device and the method for manufacturing the semiconductor device which includes a MOS field effect transistor (MOSFET) diode formed by an SOI technique.

2. Related Art

A technique which forms a semiconductor device into a thin semiconductor film formed on an insulating film (i.e., the SOI technique) has developed and put to practical use as a low power semiconductor device for the next generation. On the other hand, Spring Drive (registered trademark) is a new power source that generates electric power by unwinding a main spring, so that it is expected that the application of Spring Drive to an environmental-friendly low power system for the next generation.

In a case when Spring Drive (hereafter referred to as SD) is used as a power for driving an integrated circuit which is formed by the SOI technique, an output from SD is an alternating current so that a power circuit is required for converting the alternating current to a direct current. A diode is an essential for the power circuit, and a discrete component used as a rectifying diode is provided as an external part of an IC chip in the present state. Having the discrete component prevents the system from reducing in size. Therefore, if the IC chip has the rectifying diode built-in, the system can be made more compact in size so that the cost of the system can be reduced, and yield can be improved by reducing the number of parts.

In a case when the IC chip has the rectifying diode built-in is manufactured by the SOI technique, it is considered difficult to manufacture a pn junction diode as compared with a case of using a bulk silicon, since an SOI layer is thin. Thus, using a MOS transistor as the diode is considered as a solution. However, in this type of diode (hereafter called as a MOSFET diode), in order to obtain a necessary forward current, either decreasing a channel length or increasing a channel width is required.

In regard to decreasing the channel length, there are processing limits for using a photolithography technique. Therefore, increasing the channel width is a practical solution for increasing the forward current. In such a case, as shown in FIG. 10, for example, a gate electrode 91 of a MOSFET diode 90 is in a shape that is extremely long in one direction, and it causes a problem that lowering the efficiency of the use of a layout. JP-A-2000-58826 and JP-A-6-13574 are examples of related art.

### SUMMARY

An advantage of the invention is to provide a semiconductor device and a method for manufacturing the semiconductor device which allows increasing a channel width of a MOS field effect transistor (MOSFET) diode efficiently, and also allows improving the efficiency of the use of a layout.

According to a first aspect of the invention, a semiconductor device includes a semiconductor layer formed on a substrate with an insulating film interposed therebetween; a gate insulating film formed on the semiconductor layer; a gate electrode which is formed on the gate insulating film, and includes a first region having a circular pattern in a plan view; a source and a drain which are respectively formed in the semiconductor layer inside and outside the first region in the plan view; and a wiring line which couples one of the source and the drain with the gate electrode. Here, the “substrate” is, for example, a silicon substrate, the “insulating layer” is, for example, a silicon oxide film (SiO₂), and the “semiconductor layer” is, for example, a silicon layer.

According to the semiconductor device, the gate electrode may include a plurality of first regions and a second region which is provided between the first regions, and may link therebetween.

According to the semiconductor device, the gate electrode may include a third region which is provided inside the first region, and may link to the first region.

According to the semiconductor device, a shape of the first region in the plan view may be in a rectangular shape. Here, the “rectangular shape” is either a square or a rectangle.

According to the semiconductor device, the first region may include a rounded vertex in the plan view.

According to the semiconductor device, the shape of the third region in the plan view may be in a cross shape.

According to the semiconductor device, the shape of the third region in the plan view may be in a lattice shape.

The semiconductor device may include an element isolation film formed on the insulating layer so as to surround the semiconductor layer. In the device, the gate electrode may be formed on the semiconductor layer surrounded by the element isolation film with the gate insulating film interposed therebetween.

According to the semiconductor device, a channel region having the circular pattern can be formed in the semiconductor layer of an active region which is in the square or the rectangle in the plan view. Therefore, a channel width can be increased efficiently. The MOSFET diode with smaller area and larger channel width W can be achieved so as to improve the efficiency of the use of a layout. With the structure, an electric field concentration at each vertex can be reduced.

According to a second aspect of the invention, a method for manufacturing a semiconductor device includes: forming a gate insulating film on a semiconductor layer which is formed on a substrate with an insulating layer interposed therebetween; forming a gate electrode on the gate insulating film so as to have a first region having a circular pattern in a plan view; forming a source and a drain respectively in the semiconductor layer inside and outside the first region in the plan view; and forming a wiring line which couples one of the source and the drain with the gate electrode. With the method, the MOSFET diode with smaller area and larger channel width can be achieved so as to improve the efficiency of the use of the layout.

### BRIEF DESCRIPTION OF THE DRAWINGS

The invention will be described with reference to the accompanying drawings, wherein like numbers reference like elements.

FIGS. 1A and 1B are diagrams showing an example of a structure of a semiconductor device according to an embodiment.

FIGS. 2A and 2B are diagrams showing a method for manufacturing the semiconductor device according to the embodiment.

FIGS. 3A and 3B are diagrams showing the method for manufacturing the semiconductor device according to the embodiment.

FIGS. 4A and 4B are diagrams showing the method for manufacturing the semiconductor device according to the embodiment.

FIGS. 5A and 5B are diagrams showing the method for manufacturing the semiconductor device according to the embodiment.

FIGS. 6A and 6B show an example of a gate electrode 15.

FIGS. 7A and 7B are diagrams showing other example of the gate electrode 15.

FIGS. 8A and 8B are diagrams showing other example of the gate electrode 15.

FIGS. 9A and 9B are diagrams showing other example of the gate electrode 15.

FIG. 10 is a diagram showing an example of related art.

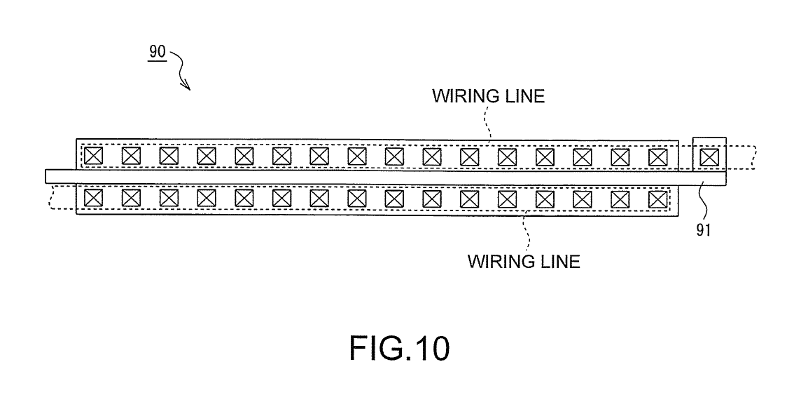

### DESCRIPTION OF EXEMPLARY EMBODIMENTS

Embodiments of the invention will now be described with reference to the accompanying drawings below. The same numerals are given to the same structure, and the overlapped description thereof will be omitted.

### First Embodiment

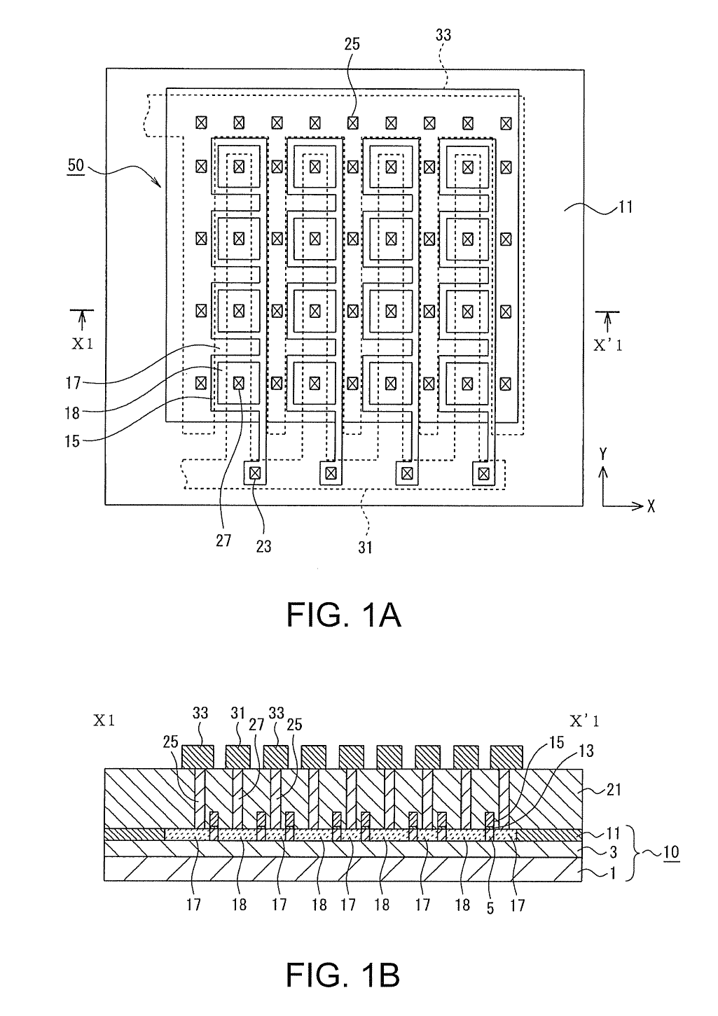

FIGS. 1A and 1B are schematic views showing an example of a structure of a semiconductor device according to a first embodiment of the invention. FIG. 1A is a schematic plan view. FIG. 1B is a cross sectional view taken along a line X1-X′1. In FIG. 1A, an interlayer insulation film is omitted in order to avoid complicated drawing.

As shown in FIGS. 1A and 1B, the semiconductor device includes an SOI substrate 10, an element isolation film 11 formed in the SOI substrate 10, and a MOS field effect transistor (MOSFET) diode 50. The MOSFET diode 50 is formed in a Si layer 5 which is a region surrounded by the element isolation film 11 (i.e., an active region) in a plan view. The SOI substrate 10 includes, for example, a bulk Si substrate 1, an insulating layer 3 formed on the Si layer 1, and the Si layer 5 (i.e., an SOI layer) formed on the insulating layer 3. The insulating film 3 is composed of a SiO₂ film, for example, and is also called a BOX layer. The element isolation film 11 is composed of the SiO₂ film, for example. As FIG. 1B shows, a bottom surface of the element isolation film 11 contacts an upper surface of the insulating layer 3. The Si layer 5 of the active region is completely isolated from its periphery by the element isolation film 11 and the insulating layer 3.

The MOSFET diode 50 includes a gate insulating film 13 formed on the Si layer 5 of the active region, a gate electrode 15 formed on the gate insulating film 13, a source and a drain (hereafter referred to as an S/D layer) 17, 18 which are respectively formed on the Si layer 5 at both sides of the gate electrode 15, a plug electrode 23 formed on the gate electrode 15, a plug electrode 25 formed on the S/D layer 17, a plug electrode 27 formed on the S/D layer 18, a wiring line 31 which electrically couples and shorts the plug electrodes 23 and 27, and a wiring line 33 which electrically couples to the plug electrode 25. The wiring lines 31 and 33 are respectively formed on the interlayer insulation film 21.

In a case when the MOSFET diode 50 shown in FIGS. 1A and 1B is an n-type, the S/D layers 17, 18 are composed of an n-type impurity diffusion layer. In the n-type MOSFET diode 50, when the wiring line 31 is coupled to a cathodic potential and the wiring line 33 is coupled to an anodic potential, a channel region which is immediately below the gate electrode 15 is inverted to the n-type so that a current flows between the S/D layers 17 and 18. In a case when the MOSFET diode 50 is a p-type, the S/D layers 17, 18 are composed of a p-type impurity diffusion layer. In the p-type MOSFET diode 50, when the wiring line 31 is coupled to the anodic potential and the wiring line 33 is coupled to the cathodic potential, the channel region which is immediately below the gate electrode 15 is inverted to the p-type so that the current flows between the S/D layers 17 and 18. The S/D layer 17, for example, is the source, and the S/D layer 18, for example, is the drain.

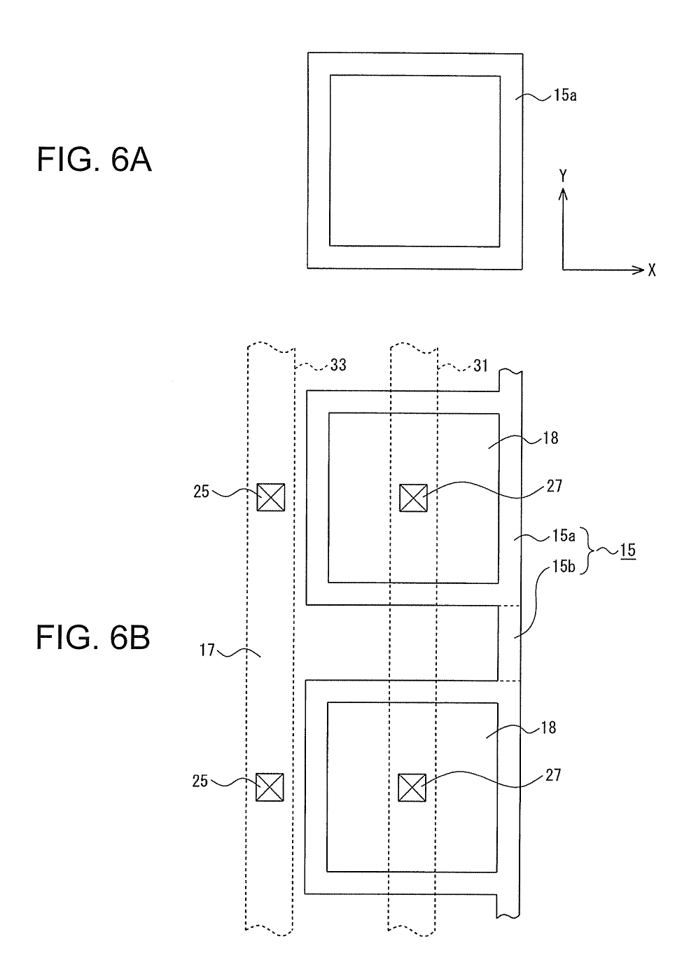

As shown in FIG. 1A, the gate electrode 15 includes a plurality of first regions having a circular pattern (i.e., a ring shape) in a plan view. As shown in FIG. 6A, for example, the gate electrode 15 includes a plurality of first regions 15a which is the gate electrode having the circular pattern in a square-like shape in the plan view. The first regions 15a are provided with a predetermined interval, for example, in an X direction and a Y direction (i.e., a direction perpendicular to the X direction in the plan view) within the region surrounded by the element isolation film (i.e., the active region). As FIG. 6B shows, for example, the gate electrode 15 includes the first region 15a and a second region 15b. The first regions 15a are adjacent to each other in the plan view. The second region 15b is provided between the first regions 15a, and links therebetween. The first region 15a and the second region 15b are respectively formed on the Si layer of the active region with the gate insulating film interposed therebetween. The S/D layers 17, 18 are respectively formed outside and inside the first region 15a in the plan view. Accordingly, a plurality of channel regions having the circular pattern can be formed in the Si layer 5 of the active region which is in a rectangle or a square in the plan view. Therefore, a channel width W can be increased efficiently.

### Second Embodiment

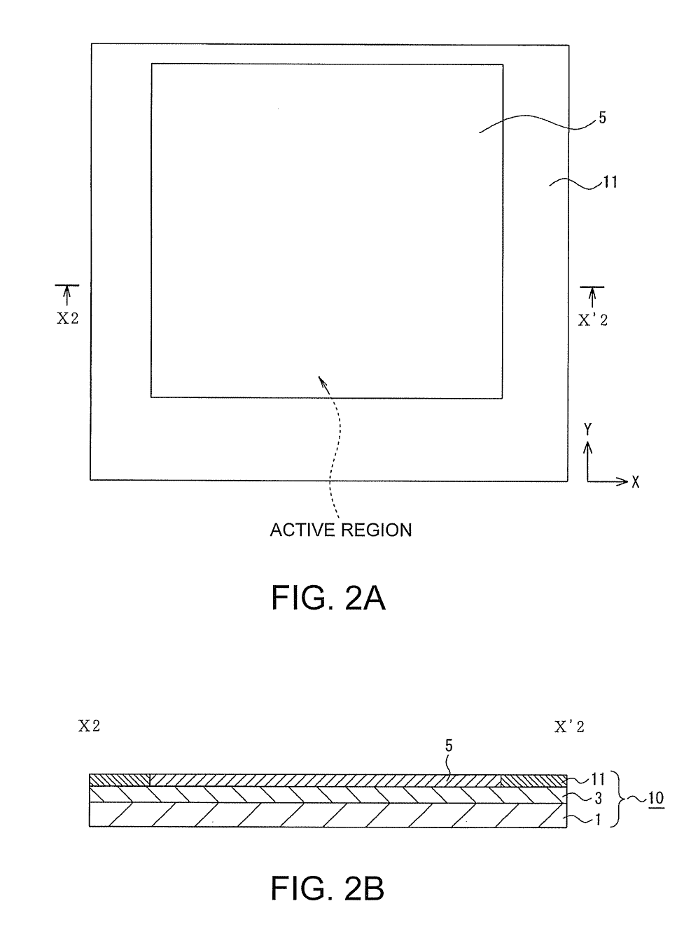

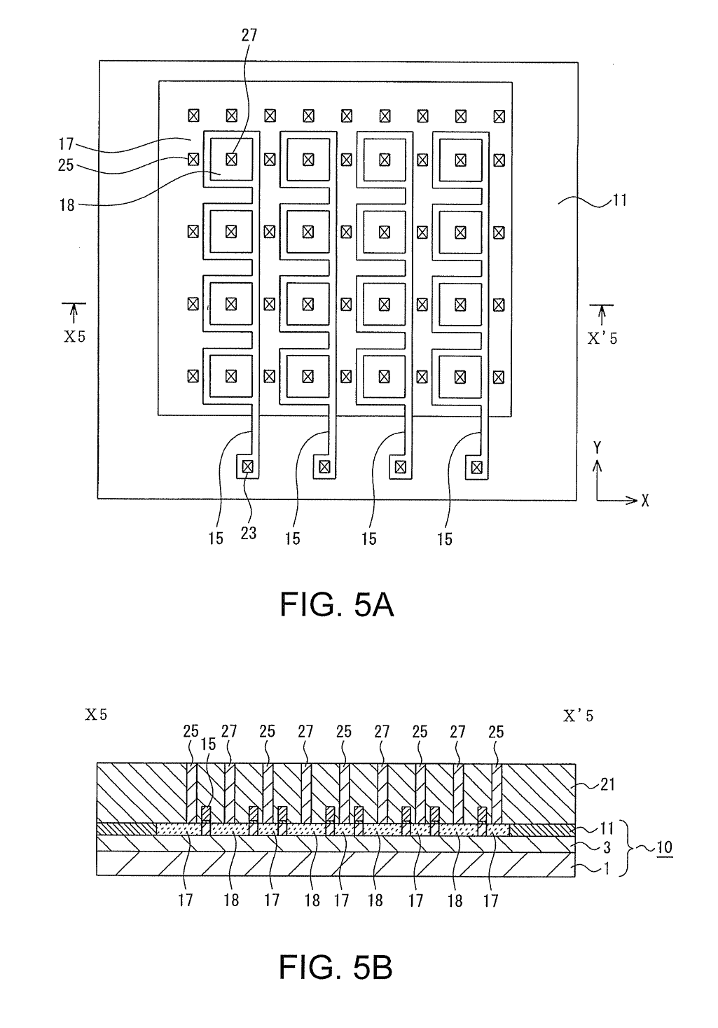

A method for manufacturing the semiconductor device shown in FIGS. 1A and 1B will now be described. FIGS. 2A to 5B are schematic views showing the method for manufacturing the semiconductor device according to a second embodiment of the invention. Each of A Figs. is a plan view, and each of B Figs. is a cross sectional view. In FIG. 5A, the interlayer insulation film is omitted in order to avoid complicated drawing. As shown in FIGS. 2A and 2B, the SOI substrate 10 is prepared. As described above, the SOI substrate 10 includes, for example, the bulk Si substrate 1, the insulating layer 3 formed on the Si substrate 1, and the Si layer 5 formed on the insulating layer 3. The SOI substrate 10 is formed by a separation by implanted oxygen (SIMOX) method or a bonding technique, for example.

As shown in FIGS. 2A and 2B, the element isolation layer 11 is formed in the SOI substrate 10. As described above, the element isolation layer 11 is composed of the SiO₂ layer, and formed by a LOCOS method or an STI method, for example. As shown in FIGS. 2A and 2B, the Si layer 5 of the active region is completely isolated from its periphery by forming the element isolation film 11. In FIGS. 2A and 2B, in order to adjust a threshold value of the MOSFET diode 50, an n-type impurity or a p-type impurity is ion-implanted into the Si layer 5 of the active region. Here, in a case when the n-type MOSFET diode 50 is formed, the p-type impurity is ion-implanted into the Si layer 5, for example. In addition, in a case when the p-type MOSFET diode 50 is formed, the n-type impurity is ion-implanted into the Si layer 5, for example. The n-type impurity is, for example, phosphorus, arsenic, or the like. The p-type impurity is, for example, boron or the like. The ion-implanting is also called a channel doping or a Vth control ion-implantation.

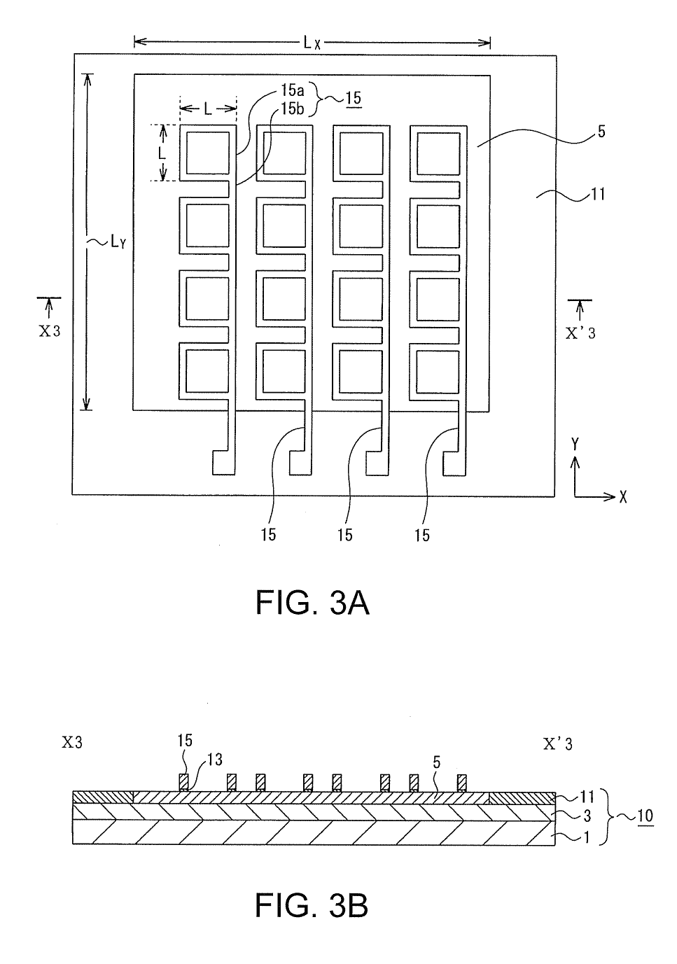

As shown in FIGS. 3A and 3B, the gate insulating film 13 is formed on a surface of the Si layer 5. The gate insulating film 13 is composed of, for example, the SiO₂ layer formed by a thermal oxidation, a silicon oxynitride film (SiON), or a high-k material film. Then, a polysilicon (poly-Si) film is formed on an entire surface of the SOI substrate 10 on which the gate insulating film 13 is formed. The polysilicon film is formed by a CVD method, for example. Here, an impurity is ion-implanted into the polysilicon film or doped with an in-situ method so as to provide conductivity to the polysilicon film.

Then, the polysilicon film is partially etched by a photolithography technique and an etching technique so as to form the gate electrode 15. Here, the gate electrode 15 which includes the first region 15a and the second region 15b is formed on the Si layer 5 of the active region with the gate insulating film 13 interposed therebetween. In FIG. 3A, for example, each of the four sides which is an outer circumference of the first region 15a is set to have the same length, and a length of one of the sides is set as L. In addition, 16 the first regions 16a in total are provided in the active region which is surrounded by the element isolation film 11. Then, the channel width (i.e., a gate width) W in the active region can be expressed as L×4×16, for example.

As an example, if L=50 μm, the gate width W=50 μm×4×16=3.2 mm. At this time, a size of the active region can be set as L_{X} is 250 μm and L_{Y} is 250 μm, for example. L_{X} is a length of one side along the X direction, and L_{Y} is the length of one side along the Y direction. Therefore, the gate electrode 15 of the gate width W=3.2 mm can be formed in the active area of an area S=250 μm×250 μm.

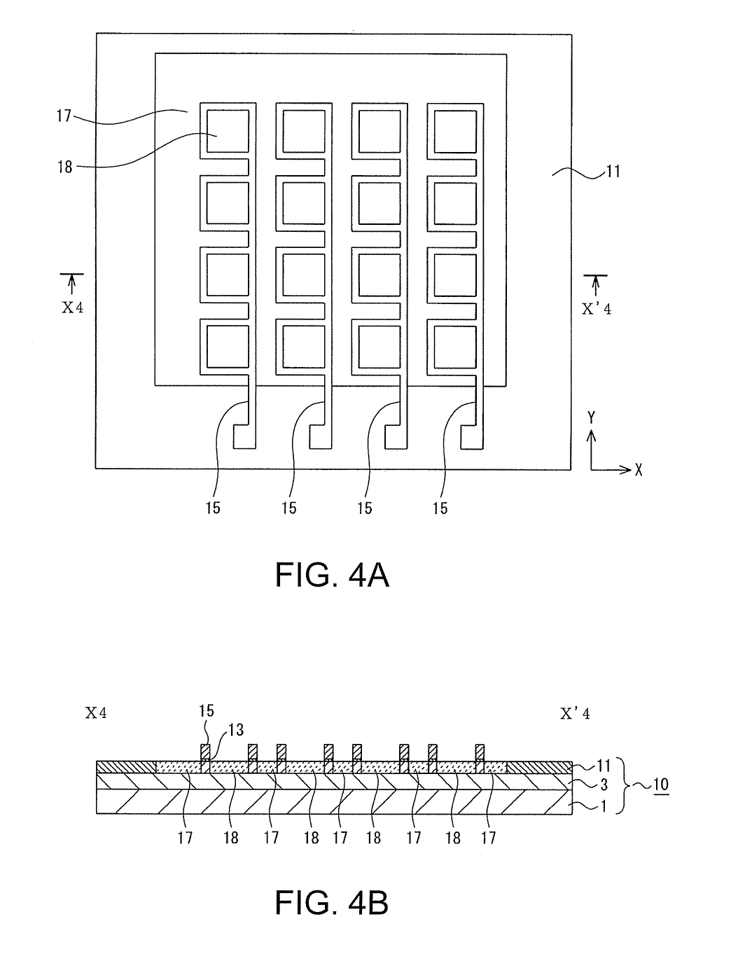

As shown in FIG. 4A, the impurity is ion-implanted into the Si layer 5, and performed a heat treatment to form the S/D layers 17, 18 using the gate electrode 15 as a mask. For example, in the case when the n-type MOSFET diode 50 is formed, the n-type impurity is ion-implanted into the Si layer 5, and performed the heat treatment to form the n-type S/D layers 17, 18. In addition, in the case when the p-type MOSFET diode 50 is formed, the p-type impurity is ion-implanted into the Si layer 5, and performed the heat treatment to form the p-type S/D layers 17, 18. The n-type impurity is, for example, phosphorus, arsenic, or the like. The p-type impurity is, for example, boron or the like. Thus, the S/D layers 17, 18 are respectively formed both sides of the gate electrode 15. That is, the S/D layer 17 is formed outside the first region 15a, and the S/D layer 18 is formed inside the first region.

As shown in FIGS. 5A and 5B, the interlayer insulation film 21 is formed on the entire upper surface of the Si substrate 1. The interlayer insulation film 21 is partially etched by the photolithography technique and the etching technique so as to respectively form a contact hole on the gate electrode 15 and the S/D layers 17, 18. Furthermore, the plug electrodes 23, 25, 27 are respectively formed in the contact hole so that the gate electrode 15 and the S/D layers 17, 18 are respectively pulled out on the interlayer insulation film 21.

Thereafter, a conductive film, such as aluminum is formed on the interlayer insulation film 21 by a sputtering technique, for example. Then the conductive film is partially etched by the photolithography technique and the etching technique so as to form the wiring lines 31 and 33. As shown in FIGS. 1A and 1B, the wiring line 31 electrically couples and shorts the S/D layer (e.g., the drain) 18 and the gate electrode 15, and the wiring line 33 electrically couples to the S/D layer (e.g., the source) 17. Thus, the MOSFET diode 50 shown in FIGS. 1A and 1B is completed.

As described above, according to the embodiment of the invention, the plurality of channel regions having the circular pattern can be formed in the Si layer 5 of the active region which is in the rectangle or the square in the plan view. Therefore, the channel width can be increased efficiently. As shown in FIG. 3A, for example, if the length of one side (L) of the first region 15a is 50 μm, the channel width W is 3.2 mm. The first region 15a is the gate electrode having the circular pattern in the square-like shape in the plan view. Then, the channel region of which the channel width W is large can be formed into the active region of the area S=250 μm×250 μm. The MOSFET diode with smaller area and larger channel width W can be achieved so as to improve the efficiency of the use of a layout. Therefore, a size of an IC chip having the MOSFET diode built-in can be reduced.

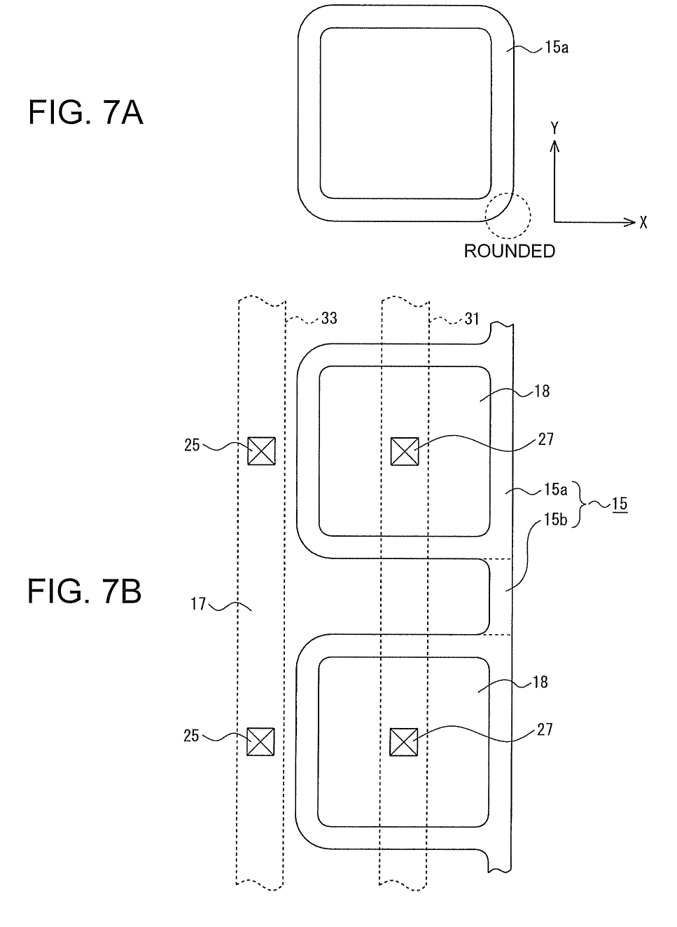

In the embodiment, the Si substrate 1 exemplarily corresponds to a “substrate” of the invention, and the Si layer 5 exemplarily corresponds to a “semiconductor layer” of the invention. Further, the S/D layer 18 exemplarily corresponds to “one of a source and a drain” of the invention, and the wiring line 31 exemplarily corresponds to a “wiring line which shorts one of the source and the drain and a gate electrode” of the invention. In the second embodiment above, as shown in FIGS. 6A and 6B, for example, in a case when the first region 15a which is included to the gate electrode 15 is in the square in the plan view, and its four vertices are square is shown. However, the shape as viewed in the plan (hereafter referred to as a planar shape) of the first region 15a is not limited to this. For example, as shown in FIGS. 7A and 7B, each vertex may be rounded in the plan view. With the structure, an electric field concentration at each vertex can be reduced. In addition, in the invention, the planer shape of the first region 15a is not limited to the square. The planer shape of the first region 15a may be in the rectangle (not shown). Further, the planer shape may be in the shape other than the rectangular shape, such as a pentagon shape, a hexagonal shape, or a circular shape as long as it has the circular pattern.

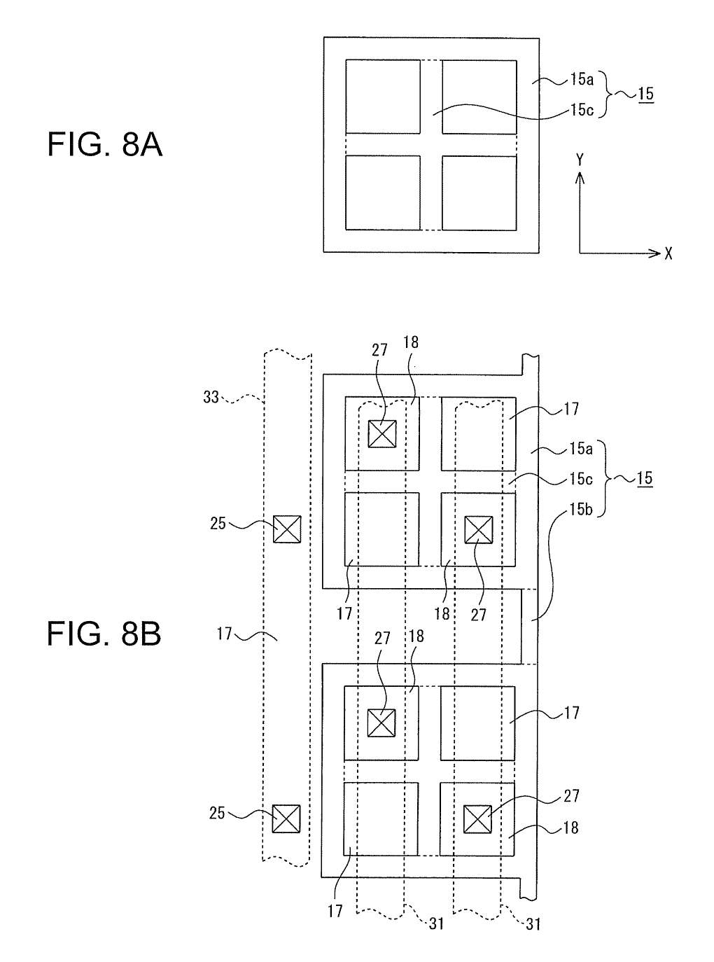

The gate electrode of the invention may have a third region other than the first and the second regions. As FIG. 8B shows, for example, the gate electrode 15 may include a third region 15c which is provided inside the first region 15a, and links thereto. The planer shape of the third region 15c may be in a cross shape, for example. The cross shape includes a first side which is parallel to the X direction and a second side which is parallel to the Y direction, for example. The first and the second sides intersect each other at respective midpoints. In such a case, as shown in FIG. 8B, the first region 15a, the second region 15b, and the third region 15c are respectively formed on the Si layer of the active region with the gate insulating film interposed therebetween. Then, the S/D layer 17 is formed outside the first region 15a, and the S/D layers 17, 18 are respectively formed inside the first region 15a. As an example, inside the first region 15a, the S/D layer 17 is provided in a pair on a diagonal line of the first region 15a. The S/D layer 18 is also provided in the pair on the diagonal line of the first region 15a.

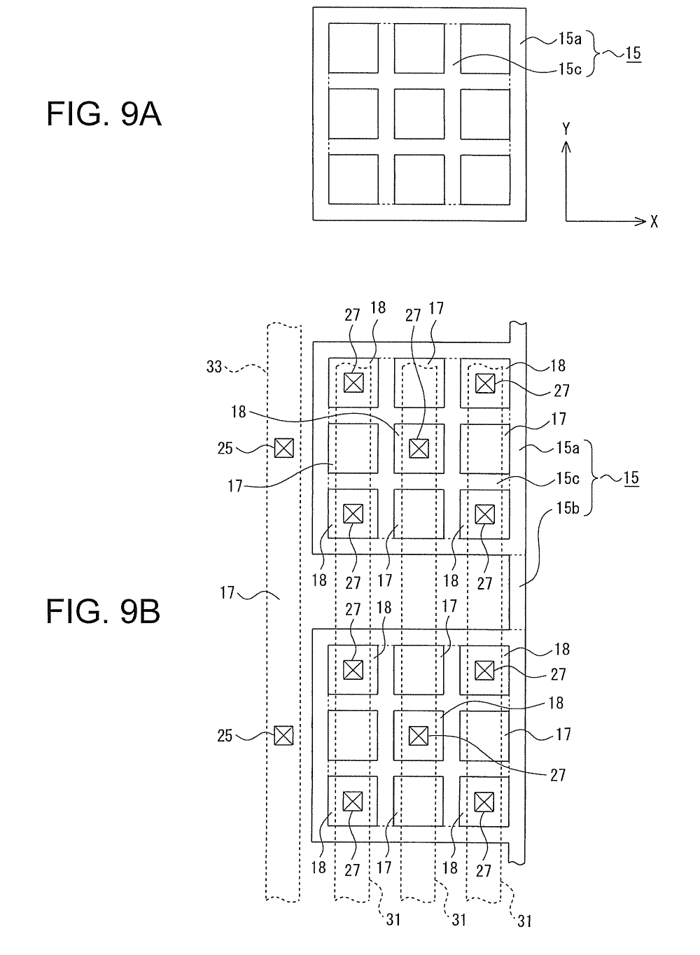

With the structure above, the plurality of channel regions having the circular pattern can be formed in the Si layer 5 of the active region which is in the rectangle or the square in the plan view. Therefore, the channel width W can be increased efficiently. Further, the planer shape of the third region 15c may be in the shape other than the cross shape. For example, as FIG. 9A shows, the planer shape of the third region 15c may be a lattice shape. The lattice shape respectively includes a plurality of first sides which are parallel to the X direction and a plurality of second sides which are parallel to the Y direction, for example. The first and the second sides respectively intersect each other with a predetermined interval. In such a case as well, as shown in FIG. 9B, for example, the first region 15a, the second region 15b, and the third region 15c are respectively formed on the Si layer of the active region with the gate insulating film interposed therebetween. Then, the S/D layer 17 is formed outside the first region 15a, and the S/D layers 17, 18 are respectively formed inside the first region 15a. As an example, inside the first region 15a, the S/D layers 17, 18 are alternately provided in the X direction and the Y direction.

With the structure above, the plurality of channel regions having the circular pattern can be formed in the Si layer 5 of the active region which is in the rectangle or the square in the plan view. Therefore, the channel width W can be increased efficiently. In FIGS. 9A and 9B, two of the first sides and two of the second sides are provided. Thus, the third region 15c is formed in the lattice shape of 2×2. However, the lattice shape that the third region 15c may have is not limited to 2×2. The lattice shape may be, for example, 3×3, 4×4, and n×n. Further, the lattice shape may be 3×4, 3×5, and n×m. N and m are positive integers (i.e., natural numbers) greater than or equal to 1, and are different in value from each other.

What is claim is:

1. A semiconductor device, comprising:
a semiconductor layer formed on a substrate with an insulating film interposed therebetween;
a gate insulating film formed on the semiconductor layer;
a gate electrode which is formed on the gate insulating film, and includes a first region having a circular pattern in a plan view;
a source and a drain which are respectively formed in the semiconductor layer inside and outside the first region in the plan view; and
a wiring line which couples one of the source and the drain with the gate electrode.

2. The semiconductor device according to claim 1, wherein the gate electrode includes a plurality of first regions and a second region which is provided between the first regions, and links therebetween.

3. The semiconductor device according to claim 1, wherein the gate electrode includes a third region which is provided inside the first region, and links to the first region.

4. The semiconductor device according to claim 1, wherein a shape of the first region in the plan view is in a rectangular shape.

5. The semiconductor device according to claim 4, wherein the first region includes a rounded vertex in the plan view.

6. The semiconductor device according to claim 3, wherein the shape of the third region in the plan view is in a cross shape.

7. The semiconductor device according to claim 3, wherein the shape of the third region in the plan view is in a lattice shape.

8. The semiconductor device according to claim 1, further comprising an element isolation film formed on the insulating layer so as to surround the semiconductor layer, wherein the gate electrode is formed on the semiconductor layer surrounded by the element isolation film with the gate insulating film interposed therebetween.

9. A method for manufacturing a semiconductor device, comprising:
forming a gate insulating film on a semiconductor layer which is formed on a substrate with an insulating layer interposed therebetween;
forming a gate electrode on the gate insulating film so as to have a first region having a circular pattern in a plan view;
forming a source and a drain respectively in the semiconductor layer inside and outside the first region in the plan view; and
forming a wiring line which couples one of the source and the drain with the gate electrode.
